(19) United States
(12) Patent Application Publication
(10) Pub. No.: US 2025/0113576 A1
(43) Pub. Date: Apr. 3, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Kuei-Yu KAO, Hsinchu (TW); Shih-Yao LIN, New Taipei City (TW); Chih-Chung CHIU, Hsinchu (TW); Chen-Chin LIAO, Yilan (TW); Chun-Yu LIN, Yilan (TW); Min-Chiao LIN, Hsinchu (TW); Yung-Chi CHANG, Hsinchu (TW); Li-Jung KUO, Zhubei (TW)

(21) Appl. No.: 18/374,668

(22) Filed: Sep. 29, 2023

(51) Int. Cl. H01L 29/66; H01L 21/8234; H01L 27/088; H01L 29/06; H01L 29/423; H01L 29/775; H01L 29/786

(52) U.S. Cl. CPC H10D 64/021; H10D 30/014; H10D 30/43; H10D 30/6735; H10D 30/6757; H10D 62/121; H10D 64/017; H10D 84/0128; H10D 84/0147; H10D 84/038; H10D 84/83

(57) ABSTRACT

Embodiments of the present disclosure provide semiconductor device structures and methods of forming the same. The structure includes a source/drain region disposed over a substrate, a gate electrode layer disposed over the substrate, a first gate spacer disposed between the gate electrode layer and the source/drain region, and a dielectric spacer disposed between the gate electrode layer and the source/drain region. A first portion of the dielectric spacer is in contact with a first portion of the first gate spacer. The structure further includes a sacrificial layer disposed between a second portion of the first gate spacer and a second portion of the dielectric spacer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIG. 6 is a cross-sectional side view of the semiconductor device structure taken along line A-A of FIG. 5, in accordance with some embodiments.

FIGS. 7A-7C are various views of one of various stages of manufacturing the semiconductor device structure, in accordance with some embodiments.

FIGS. 8A-8C are various views of one of various stages of manufacturing the semiconductor device structure, in accordance with some embodiments.

FIGS. 9 and 10 are cross-sectional side views of various stages of manufacturing the semiconductor device structure, in accordance with some embodiments.

FIGS. 11A and 11B are cross-sectional top views of the semiconductor device structure taken along line B-B and line C-C of FIG. 10, respectively, in accordance with some embodiments.

FIG. 12 is a cross-sectional side view of one of various stages of manufacturing the semiconductor device structure, in accordance with some embodiments.

FIGS. 13A and 13B are cross-sectional top views of the semiconductor device structure taken along line D-D and line E-E of FIG. 12, respectively, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a semiconductor device structure including a gate spacer including straight portions and end portions at different locations, and varying angles are formed between the straight portions and the corresponding end portions. As a result, the risk of electrical short between a gate electrode layer and a source/drain region is reduced.

While the embodiments of this disclosure are discussed with respect to nanostructure channel FETs, implementations of some aspects of the present disclosure may be used in other processes and/or in other devices, such as Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

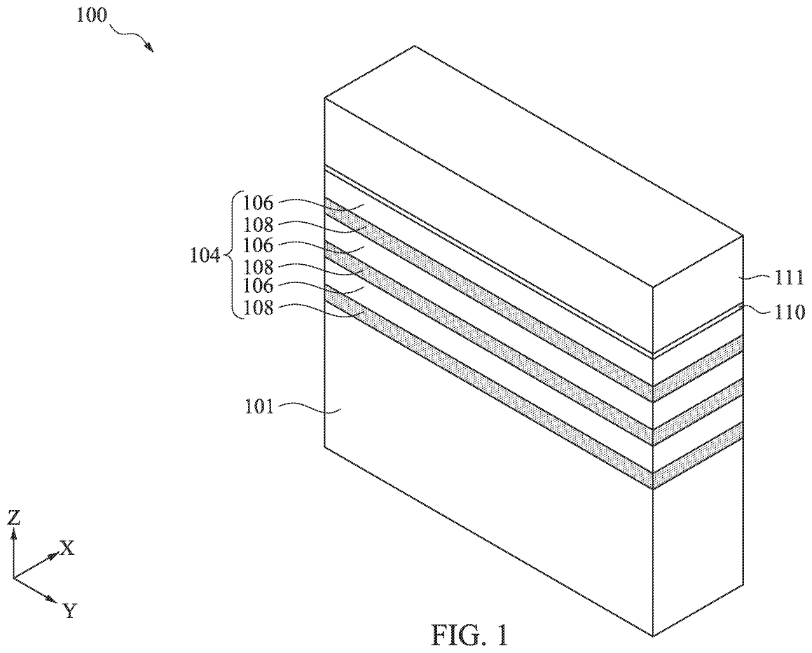

FIGS. 1-13B show exemplary processes for manufacturing a semiconductor device structure 100 according to embodiments of the present disclosure. It is understood that additional operations can be provided before, during, and after processes shown by FIGS. 1-13B, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. As shown in FIG. 1, an oxide layer 110 is formed on the topmost first semiconductor layer 106, and a nitride layer 111 is formed on the oxide layer 110. The oxide layer 110 may be silicon oxide and may have different etch selectivity compared to the nitride layer 111. The nitride layer 111 may include any suitable nitride material, such as silicon nitride. In some embodiments, the oxide layer 110 and the nitride layer 111 may be a mask structure.

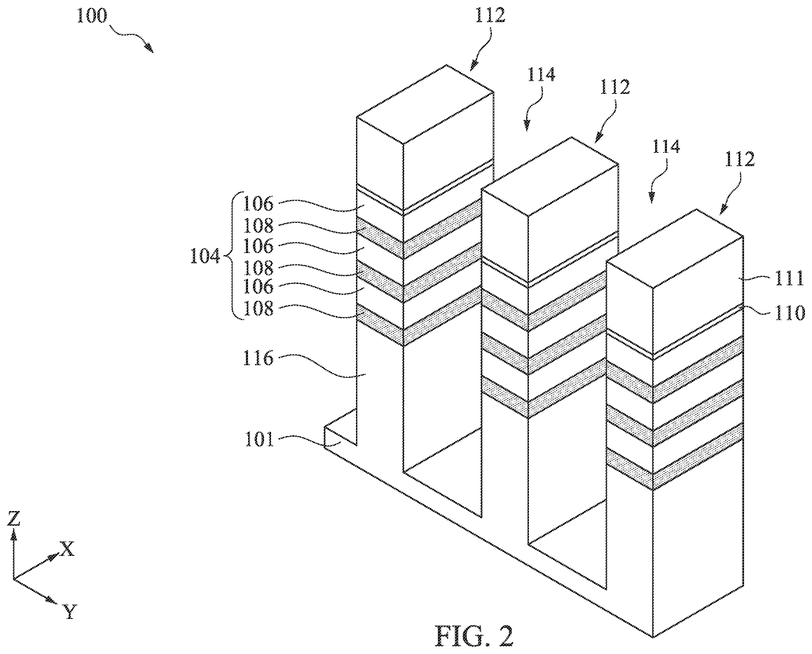

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer, such as the oxide layer 110 and the nitride layer 111, formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

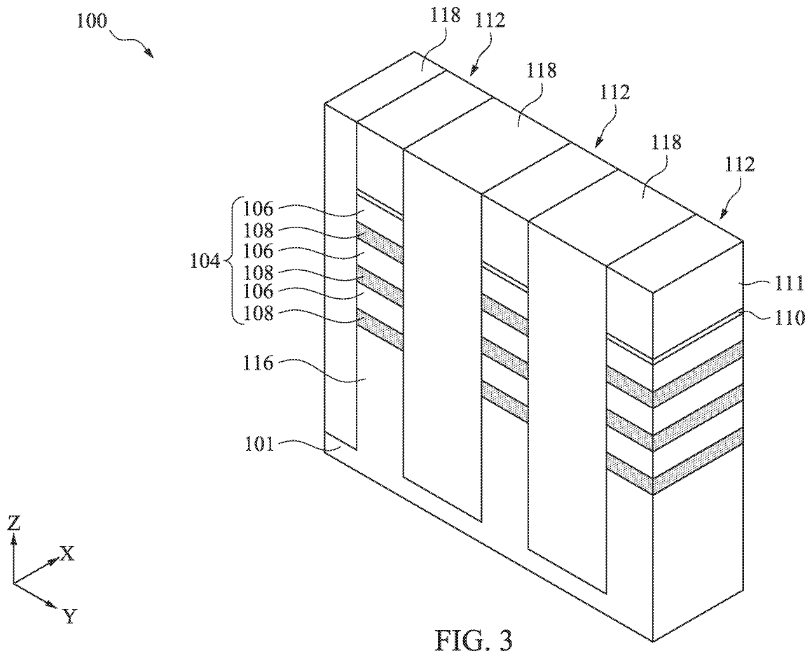

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

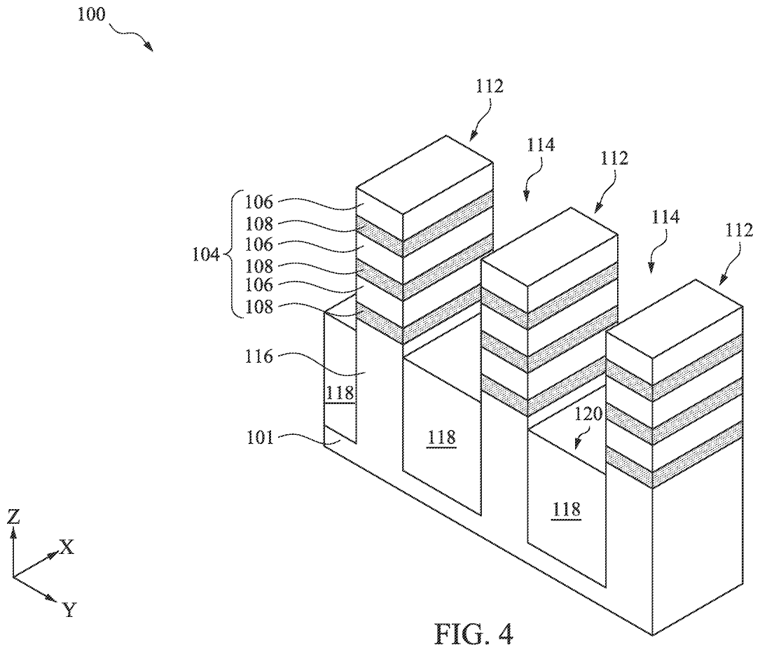

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101. In some embodiments, the isolation regions 120 are the STI. In some embodiments, the oxide layer 110 and the nitride layer 111 are also removed during the recessing of the insulating material 118.

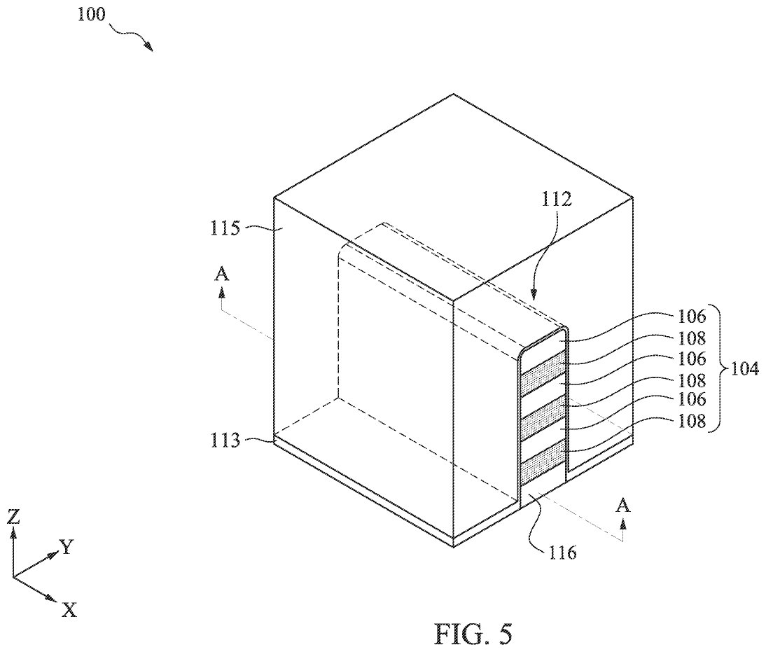

In FIG. 5, a first sacrificial layer 103 is formed on the exposed surfaces of the semiconductor device structure 100, and a second sacrificial layer 105 is formed on the first sacrificial layer 103. In some embodiments, the first sacrificial layer 103 includes a dielectric material, such as an oxide, for example silicon oxide. The first sacrificial layer 103 may be formed by any suitable process, such as CVD or PECVD. In some embodiments, the first sacrificial layer 103 is a conformal layer formed by a conformal process, such as atomic layer deposition (ALD). In some embodiments, the second sacrificial layer 105 includes a semiconductor material, such as polysilicon. The second sacrificial layer 105 may be formed by any suitable process, such as CVD, PECVD, ALD, or PVD. The second sacrificial layer 105 may be first deposited to embed the fin structures 112, followed by a planarization process, such as a CMP process. In some embodiments, the second sacrificial layer 105 may have a thickness in the Z direction ranging from about 100 nm to about 200 nm. In some embodiments, a mask layer (not shown) may be formed on the second sacrificial layer 105 after the planarization process. The mask layer may include more than one layer, such as an oxide layer and a nitride layer.

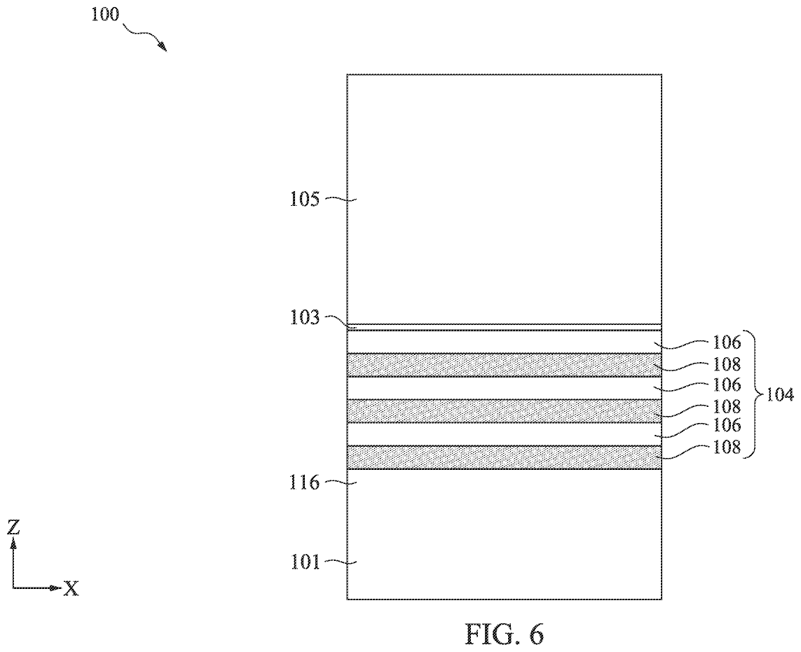

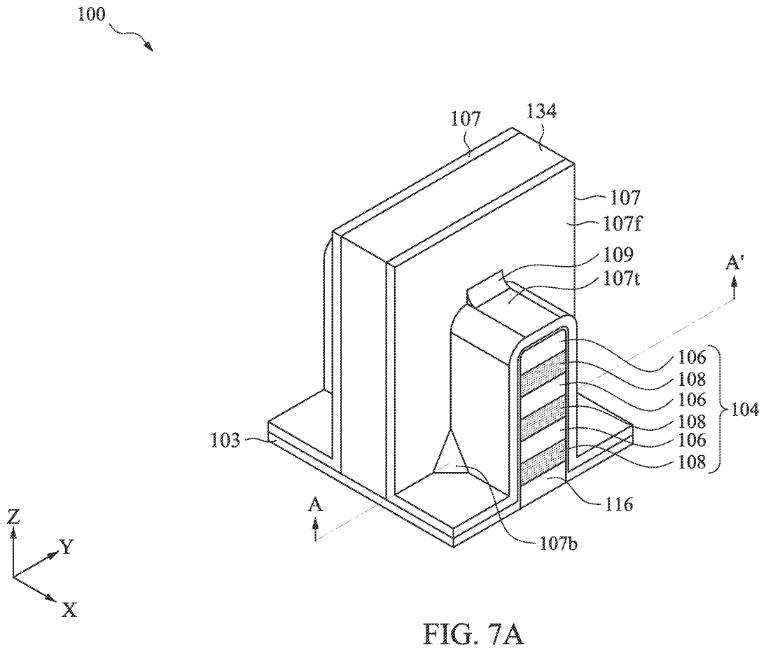

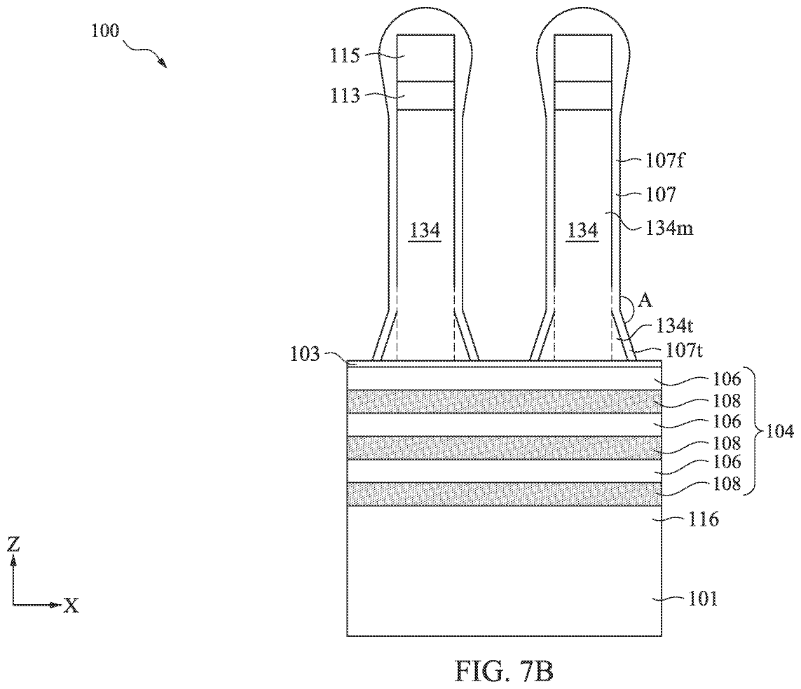

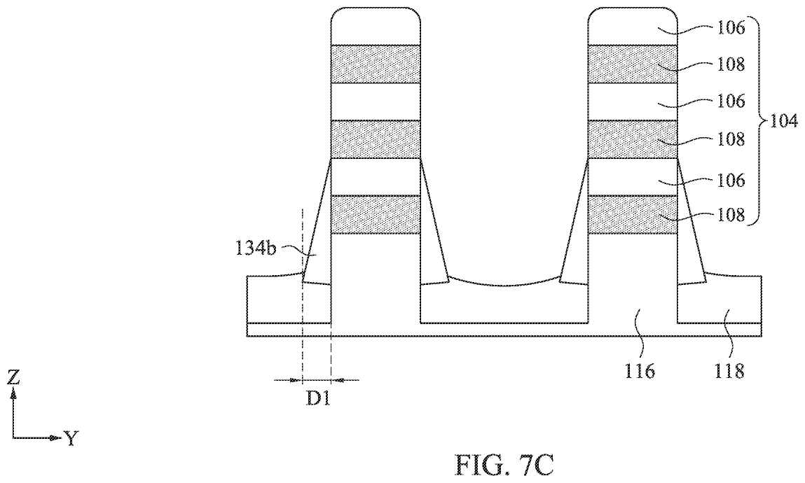

FIG. 6 is a cross-sectional side view of the semiconductor device structure 100 taken along line A-A of FIG. 5, in accordance with some embodiments. FIGS. 7A to 7C are various views of one of various stages of manufacturing the semiconductor device structure 100, in accordance with some embodiments. The mask layer is omitted in FIGS. 6, 7A, 7C, and 8A to 8C for clarity. The mask layer, which includes a nitride layer 113 and an oxide layer 115 disposed on the nitride layer 113, are shown in FIG. 7B. As shown in FIGS. 7A and 7B, the mask layer is used to pattern the second sacrificial layer 105 to form one or more sacrificial gate electrode layer 134. The patterning process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the patterning further includes an etching process that may include dry etching (e.g., RIE etching), wet etching, other etching methods, and/or combinations thereof. In some embodiments, the etching process is an anisotropic dry etching process using a chlorine-based etchant. In some embodiments, other etchants, such as HBr and/or oxygen-containing etchant, may be used. Carrier or dilute gas, such as Ar, N₂, or He, may be also used in addition to the etchants in the anisotropic dry etching process.

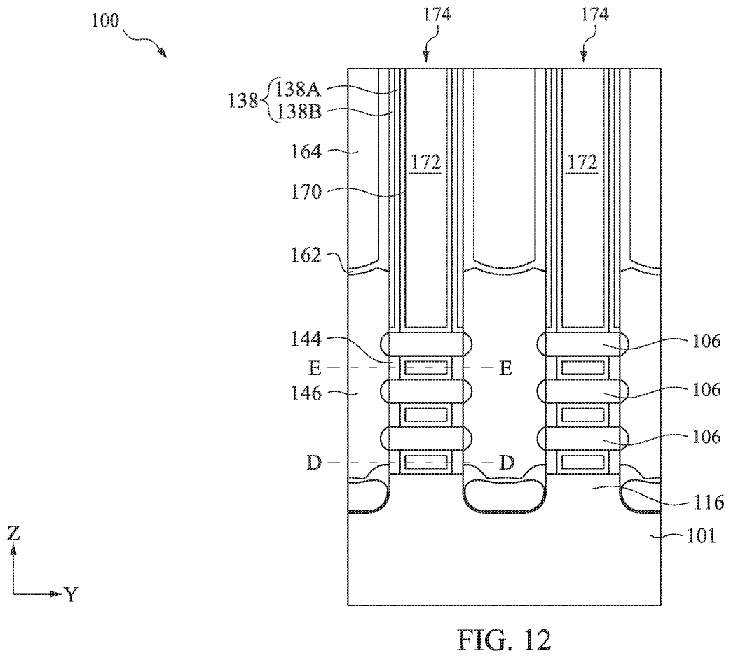

During the anisotropic dry etching process, byproducts, such as SiO, SiO—Cl, SiO—HBr, SiO—N, or SiO—Ar, may be formed on the surfaces of the semiconductor device structure 100. As a result, a byproduct layer 107 is formed on the surfaces of the semiconductor device structure 100, such as around the sacrificial gate electrode layer 134, the nitride layer 113, the oxide layer 115, and on the first sacrificial layer 103, as shown in FIGS. 7A and 7B. In some embodiments, the second sacrificial layer 105 has a thickness ranging from about 200 nm to about 300 nm, and portions of the second sacrificial layer 105 located at corners, such as between the side surface of the sacrificial gate electrode layer 134 and the portion of the first sacrificial layer 103 located on the topmost first semiconductor layer 106; and between the side surface of the sacrificial gate electrode layer 134 and the portion of the first sacrificial layer 103 located on side surfaces of the bottommost first and second semiconductor layers 106, 108, may not be removed by the anisotropic dry etching process. In addition, the byproduct layer 107 may be formed on the portions of the second sacrificial layer 105 located at corners, which makes the anisotropic etching process even harder to remove the portions of the second sacrificial layer 105, because the etchant used in the anisotropic etching process is for etching semiconductor materials, such as polysilicon. As described above, the byproduct layer 107 is a silicon oxide-based material. Furthermore, a subsequent process to remove the byproduct layer 107 may use an etchant that removes oxide. As a result, the portions of the second sacrificial layer 105 located at the corners may remain, which may lead to electrical short between a gate electrode layer 172 (FIG. 12) and the source/drain region 146 (FIG. 12).

As shown in FIGS. 7A and 7B, the byproduct layer 107 includes a first corner portion 107t located between the side surface of the sacrificial gate electrode layer 134 and the portion of the first sacrificial layer 103 located on the topmost first semiconductor layer 106. The byproduct layer 107 includes a substantially flat portion 107f, and the first corner portion 107t extends from the substantially flat portion 107f. In some embodiments, an angle A is formed between the substantially flat portion 107f and the first corner portion 107t of the byproduct layer 107, and the angle A is less than 180 degrees. In some embodiments, the angle A ranges from about 120 degrees to about 170 degrees. The first corner portion 107t may be located on both sides of the sacrificial gate electrode layer 134, as shown in FIG. 7B. The first corner portion 107t of the byproduct layer 107 may be formed on a first corner portion 134t of the sacrificial gate electrode layer 134, as shown in FIG. 7B. The sacrificial gate electrode layer 134 includes a main portion 134m and the first corner portion 134t extends from the main portion 134m on both sides of the sacrificial gate electrode layer 134. An outer surface of the main portion 134m and an outer surface of the first corner portion 134t may form an angle, and the angle may be the same as the angle A. In some embodiments, the sacrificial gate electrode layer 134 includes a top portion having substantially constant width along the X direction and a bottom portion having increasing width in a direction towards the substrate 101.

Referring to FIG. 7A, the byproduct layer 107 further includes a second corner portion 107b located between the side surface of the sacrificial gate electrode layer 134 and the portion of the first sacrificial layer 103 located on side surfaces of the bottommost first and second semiconductor layers 106, 108 not covered by the sacrificial gate electrode layer 134. The second corner portion 107b extends from the substantially flat portion 107f and is in contact with the portion of the byproduct layer 107 located adjacent the portion of the stack of semiconductor layers 104 not covered by the sacrificial gate electrode layer 134. The second corner portion 107b of the byproduct layer is formed on a second corner portion 134b (FIG. 7C) of the sacrificial gate electrode layer 134. The second corner portion 134b of the sacrificial gate electrode layer 134 may have similar shape as the second corner portion 107b.

FIG. 7C is a cross-sectional side view of the semiconductor device structure 100 taken along line A′-A′ of FIG. 7A. The byproduct layer 107 and the first sacrificial layer 103 are omitted to show the second corner portion 134b of the sacrificial gate electrode layer 134. As shown in FIG. 7C, the second corner portions 134b may be formed on opposite sides of the stack of semiconductor layers 104 not covered by the sacrificial gate electrode layer 134. The second corner portion 134b has a dimension D1 in the Y direction. In some embodiments, the dimension D1 ranges from about 4 nm to about 9 nm. The second corner portion 134b also has a dimension in the X direction ranging from about 4 nm to about 9 nm.

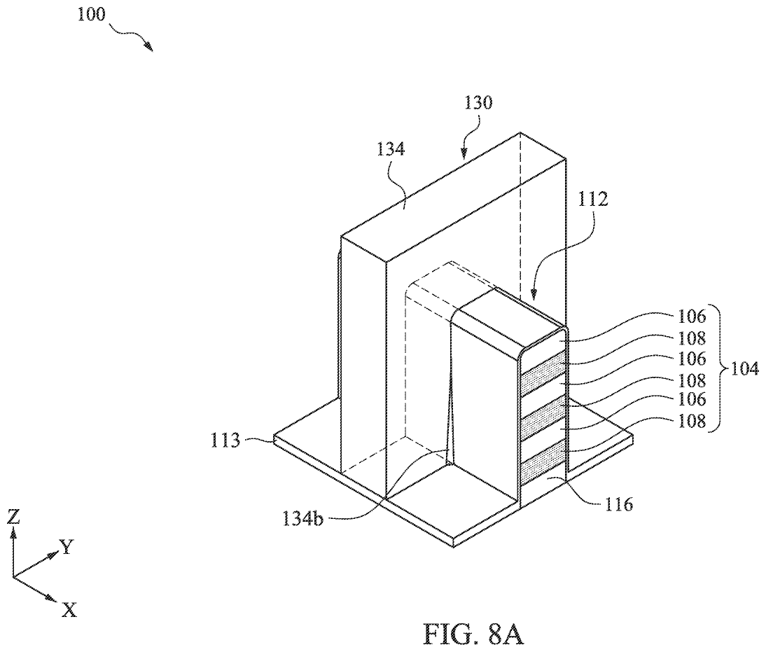

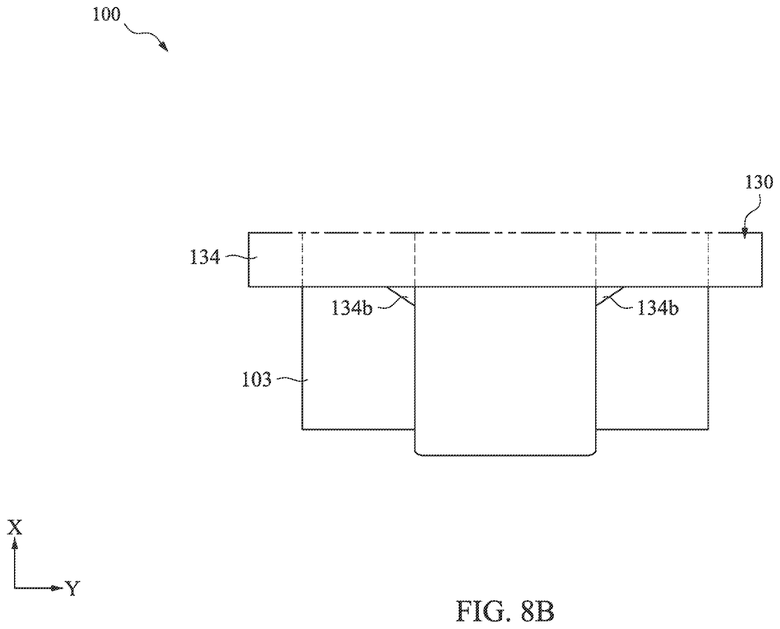

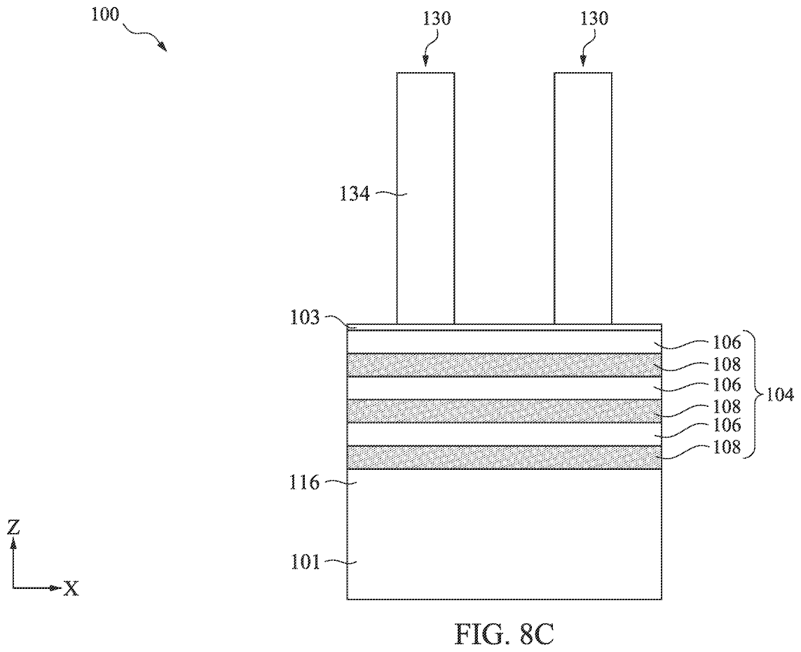

Next, as shown in FIGS. 8A to 8C, the corner portions 107f, 107b, 134t are removed and the corner portion 134b is recessed, followed by the removal of the byproduct layer 107. In some embodiments, the first and second corner portions 107f, 107b are removed by a first etching process, and the first and second corner portions 134f, 134b are removed/recessed by a second etching process. For example, the first etching process may be an anisotropic dry etching process that uses a first etchant to remove the first and second corner portions 107f, 107b of the byproduct layer 107. The first etchant may include HF, NH₃, or a combination thereof. The first etchant removes oxide-based material at a much faster rate than semiconductor materials. Furthermore, the anisotropic dry etching process is controlled to remove the first and second corner portions 107f, 107b of the byproduct layer 107, and the main portion 107m of the byproduct layer 107 is not substantially affected. The first etching process may further include a passivation gas, such as N₂, O₂, or CO₂, for selectivity and dilute gas such as He, Ar, or N₂. The flow rates of the various gases of the first etching process may range from about 20 standard cubic centimeters per minute (sccm) to about 3000 sccm. The plasma power of the first etching process may range from about 10 W to about 4000 W, and the processing pressure may range from about 1 mTorr to about 800 mTorr.

After the first etching process, the first and second corner portions 134t, 134b of the sacrificial gate electrode layer 134 are exposed. Next, the second etching process is performed to remove/recess the first and second corner portions 134t, 134b of the sacrificial gate electrode layer 134. In some embodiments, the second etching process may be an anisotropic dry etching process that uses a second etchant to remove/recess the first and second corner portions 134t, 134b. The second etchant may be different from the first etchant. In some embodiments, the second etchant is H₂. In some embodiments, the etchant used to form the sacrificial gate electrode layer 134 includes chlorine-based etchant and/or HBr and oxygen-containing etchant, and the second etchant is different from the etchant used to form the sacrificial gate electrode layer 134. The chlorine-based etchant and/or HBr and oxygen-containing etchant removes semiconductor materials, such as polysilicon, at a much faster rate than the second etchant. Using the chlorine-based etchant and/or HBr and oxygen-containing etchant to remove/recess the first and second corner portions 134t, 134b of the sacrificial gate electrode layer 134 may lead to unintended removal of portions of the stack of semiconductor layers 104 and/or the main portion 134m of the sacrificial gate electrode layer 134. The second etching process may further include a passivation gas, such as N₂, O₂, or CO₂, for selectivity and dilute gas such as He, Ar, or N₂. The flow rates of the various gases of the second etching process may range from about 20 sccm to about 3000 sccm. The plasma power of the second etching process may range from about 10 W to about 4000 W, and the processing pressure may range from about 1 mTorr to about 800 mTorr.

In some embodiments, the second corner portion 134b is not completely removed, and a small portion remains, as shown in FIGS. 8A and 8B. The dimension D1 in the Y direction and the dimension in the X direction of the remaining second corner portion 134b may be reduced to less than about 2 nm. In some embodiments, the remaining portion of the second corner portion 134b and the portion of the first sacrificial layer 103 formed on the isolation region 120 form an acute angle. The acute angle may range from about 30 degrees to about 60 degrees, such as about 45 degrees. In addition, the amount of the second corner portion 134b increases in a direction towards the substrate 101. In other words, a maximum amount of the second corner portion 134b is located adjacent the well portion 116 located below the bottommost second semiconductor layer 108, and a minimum amount of the second corner portion 134b is located adjacent the topmost first semiconductor layer 106. In some embodiments, the second corner portion 134b is completely removed.

In some embodiments, a single anisotropic dry etching process using a mixture of the first etchant and the second etchant may be performed to remove the corner portions 107f, 107b, 134f and to recess the corner portion 134b.

After the removal/recess of the corner portions 107f, 107b, 134f, 134b, a wet clean is performed to remove the byproduct layer 107, as shown in FIGS. 8A to 8C. The wet clean uses a solution that removes the oxide-based material of the byproduct layer 107 but not the semiconductor material of the sacrificial gate electrode layer 134. In some embodiments, the wet clean also removes the exposed portions of the first sacrificial layer 103. In some embodiments, an etching process is performed to remove the exposed portions of the first sacrificial layer 103. After the removal of the byproduct layer 107 and the exposed portions of the first sacrificial layer 103, the sacrificial gate electrode layer 134, the portion of the first sacrificial layer 103 disposed under the sacrificial gate electrode layer 134, and the mask layer (the nitride layer 113 and the oxide layer 115 shown in FIG. 7B) form a sacrificial gate structure 130. While two sacrificial gate structures 130 are shown in FIG. 8C, three or more sacrificial gate structures 130 may be arranged along the X direction in some embodiments.

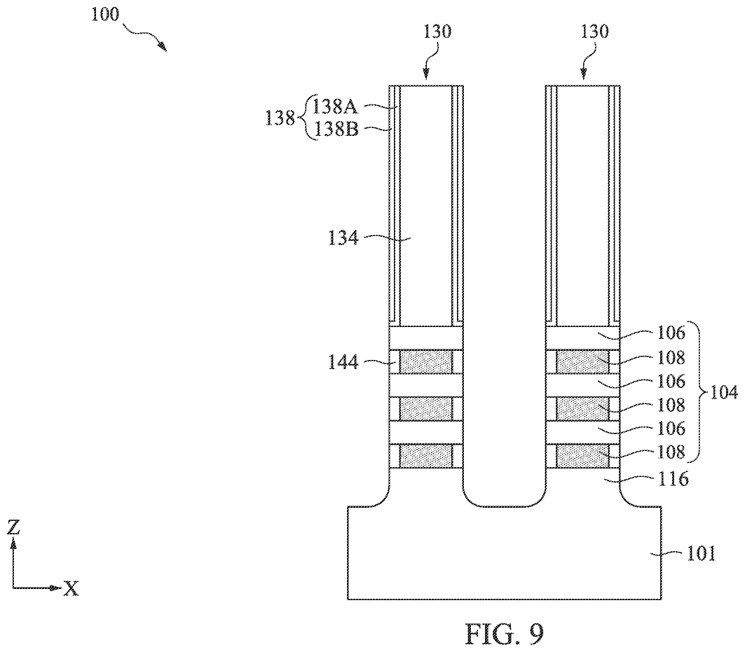

Next, as shown in FIG. 9, gate spacers 138 are formed on sidewalls of the sacrificial gate structures 130. The gate spacers 138 may be formed by conformally depositing one or more layers, such as first gate spacer 138A and second gate spacer 138B, as shown in FIG. 9, and then anisotropically etching the one or more layers, for example. The gate spacers 138A, 138B may be made of a dielectric material such as silicon oxide, silicon nitride, silicon carbide, silicon oxynitride, SiCN, silicon oxycarbide, SiOCN, and/or combinations thereof. The portions of the fin structures 112 that are covered by the sacrificial gate electrode layer 134 of the sacrificial gate structure 130 serve as channel regions for the semiconductor device structure 100.

As shown in FIG. 9, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Next, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144, as shown in FIG. 9. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

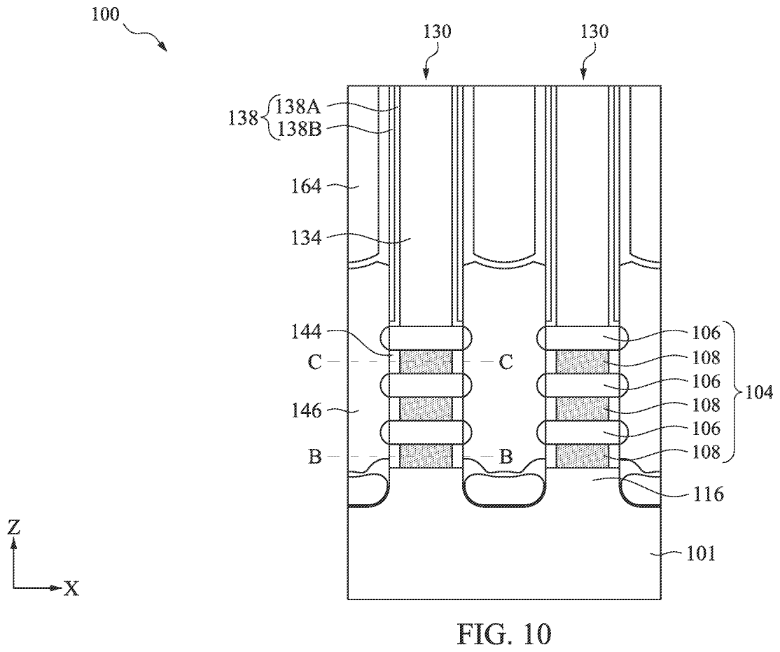

As shown in FIG. 10, source/drain (S/D) regions 146 are formed from the well portion 116. The S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

Next, as shown in FIG. 10, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 10.

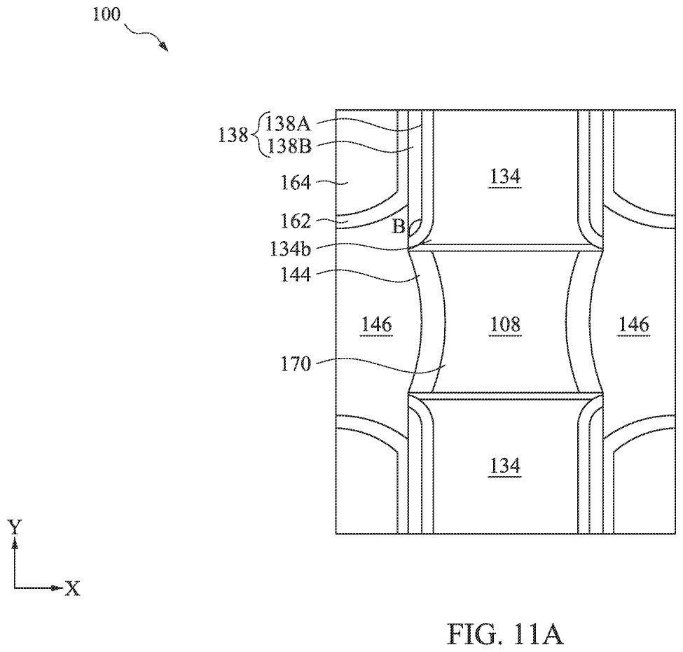

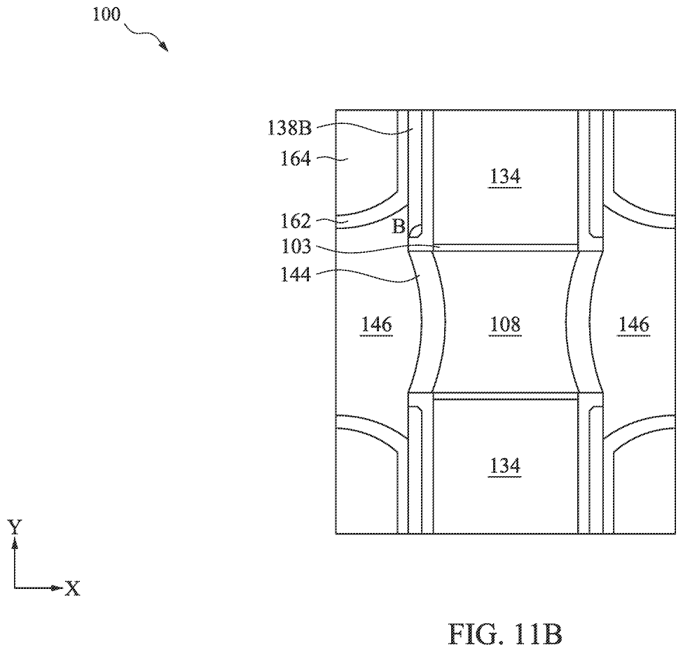

FIGS. 11A and 11B are cross-sectional top views of the semiconductor device structure 100 taken along line B-B and line C-C of FIG. 10, respectively, in accordance with some embodiments. FIG. 11A is a cross-sectional top view of a portion of the semiconductor device structure 100 taken along line B-B, which is across the bottommost second semiconductor layer 108. As shown in FIG. 11A, the second corner portion 134b remains adjacent the bottommost second semiconductor layer 108. In some embodiments, because of the existence of the second corner portion 134b of the sacrificial gate electrode layer 134, the portion of the first gate spacer 138A includes a straight portion in contact with the sidewall of the sacrificial gate electrode layer 134 and an end portion in contact with the S/D region 146, and an angle B is formed between the straight portion and the end portion. In some embodiments, the angle B is an obtuse angle due to the existence of the second corner portion 134b, as shown in FIG. 11A. For example, the angle B may range from about 105 degrees to about 130 degrees. In some embodiments, the angle B is less than 130 degrees. If the angle B is greater than about 130 degrees, the gap between the first gate spacer 138A and the first sacrificial layer 103 may be too large. As a result, the first sacrificial layer 103 may be removed to expose the S/D region 146 during the removal of the sacrificial gate stack 130. With the angle B being less than about 130 degrees, the gap between the first gate spacer 138A and the first sacrificial layer 103 is small, and the portion of the first sacrificial layer 103 in contact with the S/D region 146 is not removed during the removal of the sacrificial gate stack 130. Furthermore, because of the small gap between the first gate spacer 138A and the first sacrificial layer 103, the process window for removing the sacrificial gate stack 130 may be enlarged.

FIG. 11B is a cross-sectional top view of a portion of the semiconductor device structure 100 taken along line C-C, which is across the topmost second semiconductor layer 108. As shown in FIG. 11B, the second corner portion 134b is not present adjacent the topmost second semiconductor layer 108. Without the second corner portion 134b, the portion of the first sacrificial layer 103 is removed during the wet clean or the etching process that removes the first sacrificial layer 103 not covered by the sacrificial gate electrode layer 134. Thus, the first sacrificial layer 103 is not located between the gate spacer 138 and the dielectric spacer 144. As a result, the angle B between the straight portion and the end portion of the first gate spacer 138A is less than the angle B located adjacent the bottommost second semiconductor layer 108 (FIG. 11A). In some embodiments, the angle B adjacent the topmost second semiconductor layer 108 is a right angle. The angle B adjacent the middle second semiconductor layer 108 may be between the angle B adjacent the topmost second semiconductor layer 108 and the angle B adjacent the bottommost second semiconductor layer 108. In other words, the angle B increases in a direction towards the substrate 101.

As shown in FIG. 12, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the exposed portions of the first sacrificial layer 103, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

Portions of the second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The gate dielectric layer 170 and the gate electrode layer 172 formed over the ILD layer 164 are then removed by using, for example, CMP, until the top surface of the ILD layer 164 is exposed.

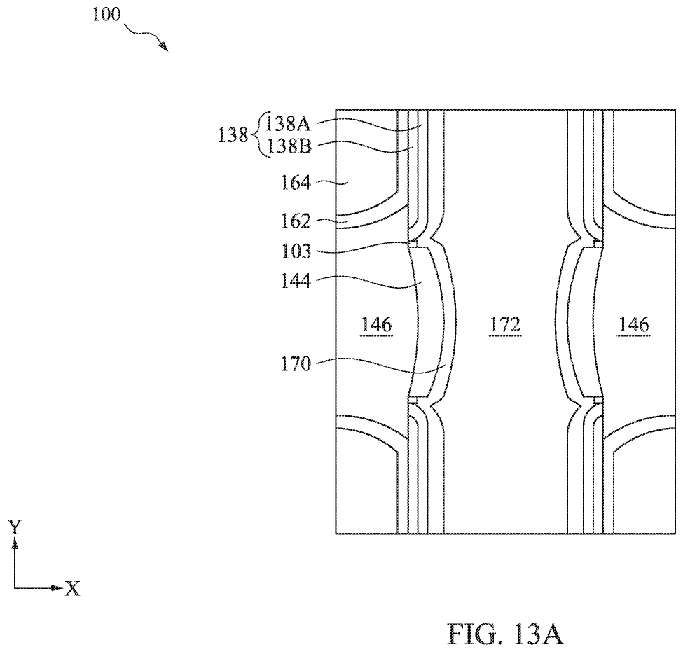

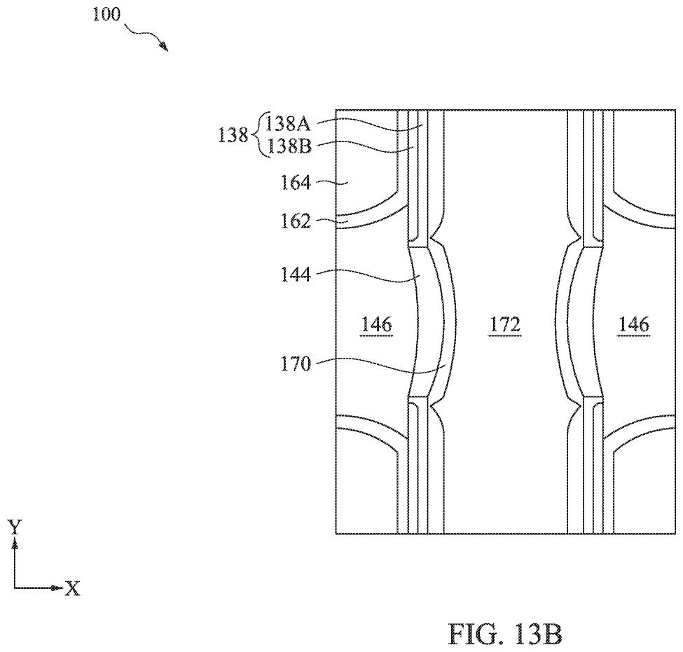

FIGS. 13A and 13B are cross-sectional top views of the semiconductor device structure 100 taken along line D-D and line E-E of FIG. 12, respectively, in accordance with some embodiments. FIG. 13A is a cross-sectional top view of a portion of the semiconductor device structure 100 taken along line D-D, which is across the portion of the gate electrode layer 172 located below the bottommost first semiconductor layer 106. As shown in FIG. 13A, the portion of the first sacrificial layer 103 located between the gate spacer 138 and the dielectric spacer 144 remains and separates the gate dielectric layer 170 and the S/D region 146. In some embodiments, the thickness of the portion of the first sacrificial layer 103 located between the gate spacer 138 and the dielectric spacer 144 along the Y direction is less than about 1 nm, such as from about 0.3 nm to about 1 nm. In some embodiments, the first sacrificial layer 103 is in contact with the S/D region 146, the first gate spacer 138A, and the dielectric spacer 144.

FIG. 13B is a cross-sectional top view of a portion of the semiconductor device structure 100 taken along line E-E, which is across the portion of the gate electrode layer 172 located below the topmost first semiconductor layer 106. As shown in FIG. 13B, the gate dielectric layer 170 and the S/D region 146 are separated by the gate spacer 138 and the dielectric spacer 144. In some embodiments, the thickness of the gate spacer 138 (the combined thickness of the first and second gate spacers 138A, 138B) may range from about 5 nm to about 10 nm, and the thickness of the dielectric spacer 144 may be the same as the thickness of the gate spacer 138. With the such thick dielectric materials between the gate dielectric layer 170 and the S/D region 146, the risk of electrical short between the gate electrode 172 and the S/D region 146 is reduced. In addition, because the gate spacer 138 is in contact with the dielectric spacer 144, the process window for removing the sacrificial gate stack 130 may be enlarged. For example, when removing the sacrificial gate electrode layer 134, the portion of the first sacrificial layer 103 covered by the sacrificial gate electrode layer 134, and the second semiconductor layers 108, the risk of exposing the S/D regions 146 is reduced.

Embodiments of the present disclosure provide a semiconductor device structure 100 including a gate spacer 138A including straight portions and end portions at different locations, and varying angles B are formed between the straight portions and the corresponding end portions. Some embodiments may achieve advantages. For example, the process to form the semiconductor device structure 100 has an enlarged process window for removing the sacrificial gate stack 130. Furthermore, the risk of electrical short between the gate electrode 172 and the S/D region 146 is reduced.

An embodiment is a semiconductor device structure. The structure includes a source/drain region disposed over a substrate, and the source/drain region includes a first portion and a second portion located over the first portion. The structure further includes a gate electrode layer disposed over the substrate, and the gate electrode layer includes a first portion and a second portion located over the first portion. The structure further includes a first gate spacer disposed between the gate electrode layer and the source/drain region, and the first gate spacer includes a first portion and a second portion located over the first portion. The structure further includes a dielectric spacer disposed between the gate electrode layer and the source/drain region, the dielectric spacer includes a first portion and a second portion located over the first portion, and the second portion of the dielectric spacer is in contact with the second portion of the first gate spacer. The structure further includes a sacrificial layer disposed between the first portion of the first gate spacer and the first portion of the dielectric spacer.

Another embodiment is a semiconductor device structure. The structure includes a source/drain region disposed over a substrate, and the source/drain region includes a first portion and a second portion located over the first portion. The structure further includes a gate electrode layer disposed over the substrate, and the gate electrode layer includes a first portion and a second portion located over the first portion. The structure further includes a first gate spacer disposed between the gate electrode layer and the source/drain region, and the first gate spacer includes a first portion and a second portion located over the first portion. The first portion includes a first main portion, a first end portion, and a first angle formed between the first main portion and the first end portion. The second portion includes a second main portion, a second end portion, and a second angle formed between the second main portion and the second end portion. The second angle is different from the first angle.

A further embodiment is a method for forming a semiconductor device structure. The method includes forming a fin structure from a substrate, depositing a first sacrificial layer around the fin structure, depositing a second sacrificial layer on the first sacrificial layer, and performing a first etching process to form a sacrificial gate electrode layer. A byproduct layer is formed on the sacrificial gate electrode layer, and the sacrificial gate electrode layer and the byproduct layer each includes one or more corner portions. The method further includes performing a second etching process to remove the one or more corner portions of the byproduct layer and to expose the one or more corner portions of the sacrificial gate electrode layer, performing a third etching process to remove at least one of the one or more corner portions of the sacrificial gate electrode layer, removing a portion of the fin structure to expose a well portion, and forming a source/drain region from the exposed well portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain region disposed over a substrate, wherein the source/drain region includes a first portion and a second portion located over the first portion;
a gate electrode layer disposed over the substrate, wherein the gate electrode layer includes a first portion and a second portion located over the first portion;
a first gate spacer disposed between the gate electrode layer and the source/drain region, wherein the first gate spacer includes a first portion and a second portion located over the first portion;
a dielectric spacer disposed between the gate electrode layer and the source/drain region, wherein the dielectric spacer includes a first portion and a second portion located over the first portion, and the second portion of the dielectric spacer is in contact with the second portion of the first gate spacer; and
a sacrificial layer disposed between the first portion of the first gate spacer and the first portion of the dielectric spacer.

2. The semiconductor device structure of claim 1, wherein the sacrificial layer is in contact with the first portion of the source/drain region.

3. The semiconductor device structure of claim 1, further comprising a gate dielectric layer including a first portion and a second portion located over the first portion, wherein the first portion of the gate dielectric layer is disposed between the sacrificial layer and the first portion of the gate electrode layer.

4. The semiconductor device structure of claim 3, wherein the second portion of the gate dielectric layer is in contact with the second portion of the first gate spacer and the second portion of the dielectric spacer.

5. The semiconductor device structure of claim 1, further comprising a second gate spacer including a first portion and a second portion located over the first portion.

6. The semiconductor device structure of claim 5, wherein the first portion of the first gate spacer and the first portion of the second gate spacer has a combined thickness ranging from about 5 nm to about 10 nm.

7. The semiconductor device structure of claim 6, wherein the first portion of the dielectric spacer has a thickness ranging from about 5 nm to about 10 nm.

8. A semiconductor device structure, comprising:
a source/drain region disposed over a substrate, wherein the source/drain region includes a first portion and a second portion located over the first portion;
a gate electrode layer disposed over the substrate, wherein the gate electrode layer includes a first portion and a second portion located over the first portion; and
a first gate spacer disposed between the gate electrode layer and the source/drain region, wherein the first gate spacer includes a first portion and a second portion located over the first portion, the first portion includes a first main portion, a first end portion, and a first angle formed between the first main portion and the first end portion, and the second portion includes a second main portion, a second end portion, and a second angle formed between the second main portion and the second end portion, wherein the second angle is different from the first angle.

9. The semiconductor device structure of claim 8, wherein the first angle is an obtuse angle, and the second angle is a right angle.

10. The semiconductor device structure of claim 9, wherein the first angle ranges from about 105 degrees to about 130 degrees.

11. The semiconductor device structure of claim 8, further comprising a first semiconductor layer and a second semiconductor layer disposed over the first semiconductor layer, wherein the first portion of the gate electrode layer is disposed below the first semiconductor layer, and the second portion of the gate electrode layer is disposed over the second semiconductor layer.

12. The semiconductor device structure of claim 11, wherein the first portion of the first gate spacer is disposed between the first portion of the gate electrode layer and the first portion of the source/drain region, and the second portion of the first gate spacer is disposed between the second portion of the gate electrode layer and the second portion of the source/drain region.

13. The semiconductor device structure of claim 12, further comprising a sacrificial layer in contact with the first portion of the source/drain region and the first portion of the first gate spacer.

14. The semiconductor device structure of claim 8, further comprising a second gate spacer including a first portion and a second portion located over the first portion.

15. The semiconductor device structure of claim 14, wherein the first portion of the first gate spacer and the first portion of the second gate spacer has a combined thickness ranging from about 5 nm to about 10 nm.

16. A method for forming a semiconductor device structure, comprising:
forming a fin structure from a substrate;
depositing a first sacrificial layer around the fin structure;
depositing a second sacrificial layer on the first sacrificial layer;
performing a first etching process to form a sacrificial gate electrode layer, wherein a byproduct layer is formed on the sacrificial gate electrode layer, and the sacrificial gate electrode layer and the byproduct layer each includes one or more corner portions;
performing a second etching process to remove the one or more corner portions of the byproduct layer and to expose the one or more corner portions of the sacrificial gate electrode layer;
performing a third etching process to remove at least one of the one or more corner portions of the sacrificial gate electrode layer;
removing a portion of the fin structure to expose a well portion; and
forming a source/drain region from the exposed well portion.

17. The method of claim 16, further comprising performing a wet clean to remove the byproduct layer after performing the third etching process.

18. The method of claim 16, wherein the first etching process uses a first etchant, the second etching process uses a second etchant different from the first etchant, and the third etching process uses a third etchant different from the first and second etchants.

19. The method of claim 18, wherein the first etchant is a chlorine-based etchant, the second etchant comprises HF, NH₃, or a combination thereof, and the third etchant comprises H₂.

20. The method of claim 16, wherein the third etching process recesses at least one of the one or more corner portions of the sacrificial gate electrode layer.
